(19) United States
(12) Patent Application Publication
(10) Pub. No.: US 2021/0327825 A1
(43) Pub. Date: Oct. 21, 2021

(54) INTEGRATED CIRCUIT PACKAGE COMPRISING AN ENHANCED ELECTROMAGNETIC SHIELD

(71) Applicants: Chunrong LU, San Diego, CA (US); Anna Katharina KREFFT, San Diego, CA (US); Li AN, San Diego, CA (US); QUALCOMM Incorporated, San Diego, CA (US)

(72) Inventors: Chunrong LU, Wuxi (CN); Anna Katharina KREFFT, Munich (DE); Li AN, Wuxi (CN)

(21) Appl. No.: 17/247,185

(22) PCT Filed: Jul. 27, 2018
(86) PCT No.: PCT/CN2018/097317

§ 371 Date: Dec. 3, 2020

(51) Int. Cl. H01L 23/552; H01L 23/31; H01L 21/48; H01L 21/56

(52) U.S. Cl. CPC H01L 23/552; H01L 21/566; H01L 21/4814; H01L 23/3121

(57) ABSTRACT

Some features pertain to a package, comprising a substrate, an electronic component coupled to the substrate, a mold at least partially surrounding the electronic component and a first shield over the mold, and a second shield over the first shield, the first shield made of a material selected to have a high permeability shield. The package includes an enhanced electromagnetic shield.

### CLAIM OF PRIORITY

This application claims the benefit of and priority to International Patent Cooperation Treaty Application No. PCT/CN2018/097317, filed Jul. 27, 2018, which are both hereby assigned to the assignee hereof and hereby expressly incorporated by reference herein as if fully set forth below and for all applicable purposes.

### BACKGROUND

### Field of the Disclosure

Various features relate to an enhanced electromagnetic shield for an integrated circuit package.

### Background

Integrated circuits, integrated circuit packages and electronic devices are being continually driven to smaller form factors. Smaller form factors are needed so that such devices may be integrated into mobile devices such as mobile phones, tablets, laptops, etc. Integrated circuit packages include several components such as a substrate, and electronic devices including die, integrated circuits, and passive devices. These electronic devices including die, integrated circuits, and passive devices, require electromagnetic shielding. An electromagnetic shield protects the electronic devices from radio frequencies, electromagnetic fields and electrostatic fields. Likewise, the electromagnetic shield protects electronic devices outside of the electromagnetic shield, from radio frequencies, electromagnetic fields and electrostatic fields generated by the electronic devices on the integrated circuit package. A challenge exists in achieving a small form factor electromagnetic shield with improved shielding effectiveness.

FIG. 1 illustrates a package including a conventional shield. Specifically, FIG. 1 illustrates an integrated circuit (IC) package 100, the IC package 100 including a substrate 102, electronic components 110 and 112 (e.g., a die, or passive components), a mold 120, and a shield 140. The shield 140 is sputtered onto the mold 120. The shield 140 is sputtered so that the height of the shield can be kept smaller. However, one drawback is the sputtering process requires the metal grain of the shield 140 be small (e.g., tens of nanometers). Small grain size results in a reduced shielding effectiveness. Another drawback is that where use of a high permeability material is desired (e.g., as the first shield), the sputtering process does not maintain the high permeability due to the rearrangement of the small grain size.

Accordingly, there is an industry need for increased shielding effectiveness, while maintaining a small form factor. In other words, there is an industry need for an electromagnetic shield with increased shielding effectiveness, that does not significantly increase the height of the IC package 100.

### SUMMARY

Various features relate to an enhanced electromagnetic shield for an integrated circuit package.

A first example provides a package including a substrate, an electronic component coupled to the substrate, a mold at least partially surrounding the electronic component and coupled to the substrate, a first shield over the mold, and a second shield over the first shield. The first shield is a high permeability shield.

A second example provides a method of fabricating an integrated circuit package, including coupling an electronic component to a substrate, coupling the electronic component and substrate to a mold, the mold at least partially surrounding the electronic component, and coupling a first shield over the mold.

### DRAWINGS

Various features, nature and advantages may become apparent from the detailed description set forth below when taken in conjunction with the drawings in which like reference characters identify correspondingly throughout.

FIG. 1 illustrates a package including a conventional shield.

FIG. 2 illustrates a side view of an integrated circuit package including an enhanced electromagnetic shield.

FIGS. 3A-3F illustrates an exemplary sequence for manufacturing an integrated circuit package comprising an enhanced electromagnetic shield.

FIG. 4 illustrates an exemplary flow diagram of a method for manufacturing an integrated circuit package including an enhanced electromagnetic shield.

FIG. 5 illustrates various electronic devices that may include the various substrates, integrated devices, integrated device packages, semiconductor devices, dies, integrated circuits, and/or packages described herein.

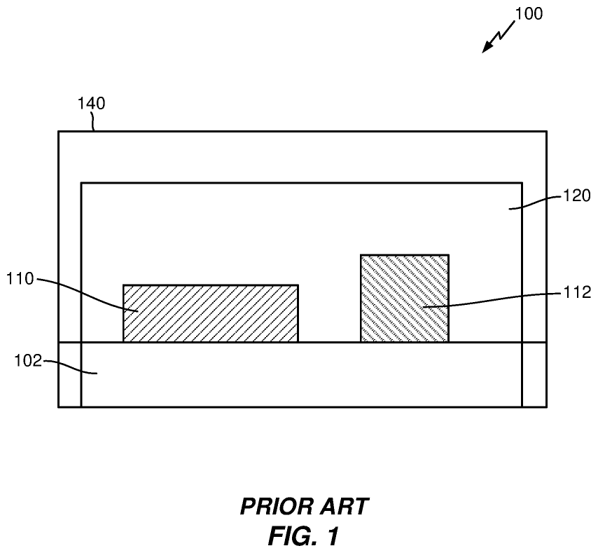

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams to avoid obscuring the aspects in unnecessary detail. In other instances, well-known circuits, structures and techniques may not be shown in detail in order not to obscure the aspects of the disclosure.

### Overview

Some features pertain to a package that includes an electronic component coupled to the substrate including an enhanced electromagnetic shield. A mold at least partially surrounds the electronic component and is coupled to the substrate. A first shield is located over the mold, and a second shield is located over the first shield. The first shield and the second shield are electromagnetic shields, configured to reduce electromagnetic interference to the electronic components within the package, and to electronic components outside of the package.

An optional adhesive layer (e.g., solder resist layer) may be placed over the mold and under the first shield. The optional adhesive layer increases adhesiveness between the first shield and the mold.

The mold includes mold sidewalls (i.e., a plurality of mold sidewalls), the first shield includes first shield sidewalls (i.e., a plurality of first shield sidewalls), and the substrate includes substrate sidewalls (i.e., a plurality of substrate sidewalls). The first shield is located over the mold and my also be located over the optional adhesive layer. In one aspect, the first shield may not be over the mold sidewalls. The second shield is located over the first shield, over the first shield side walls, over the mold sidewalls, and over the substrate sidewalls.

The first shield is a high permeability shield. That is, the first shield is made of a material selected to have a high permeability. A high permeability material is a material that has a permeability larger than 10 H/m. The first shield may have a higher permeability relative to the second shield. The first shield may have soft magnetic properties. The first shield is an electromagnetic shield that is configured to enhance the shielding effectiveness.

The second shield may have a lower permeability relative to the first shield in order to achieve a reduced height. Because the first shield has higher permeability relative to the second shield, the first shield provides enhanced electromagnetic shielding of multi-frequency bandwidths. The package may include a multi-layer shield including a plurality of the first shield or the second shield or both. In one aspect, the package may include a first shield (e.g., high permeability shield) over the mold, a second shield (e.g. sputtered shield) over the first shield, and a third shield over the second shield where the third shield is a high permeability shield. In another aspect, the package may include a fourth shield over the third shield.

### Integrated Circuit Package Comprising an Enhanced Electromagnetic Shield

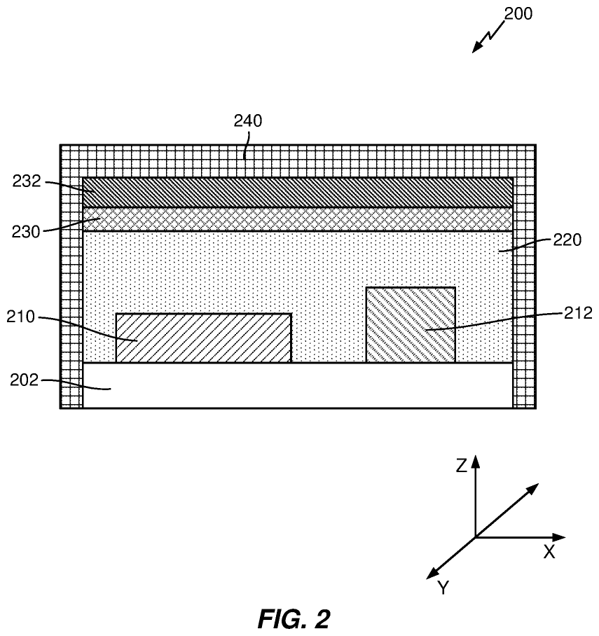

FIG. 2 illustrates a side view of an integrated circuit package including an enhanced electromagnetic shield. Specifically, FIG. 2 illustrates an integrated circuit (IC) package 200. The IC package 200 includes a substrate 202, electronic components 210 and 212, a mold 220, an optional adhesive layer 230, a first shield 232, and a second shield 240. It shall be understood that FIG. 2 is a simplified drawing of the IC package 200. The IC package 200 may include additional elements not shown such as dielectric layers, passivation layers, metal layers, and electronic components embedded in the substrate 202 or in a silicon substrate of one of the electronic components 210.

The substrate 202 may be a package substrate. Alternatively, at least one of the electronic components 210 or 212 and the substrate 202 together may comprise a wafer level package. The substrate 202 includes substrate sidewalls. The substrate 202 may be coupled to ground.

The electronic component 210 may be an IC, a die, a passive device or any other type of electronic component. The electronic component 212 may be an IC, a die, a passive device or any other type of electronic component. The IC package 200 may only have a single electronic component (e.g., one of 210 or 212) or may have many electronic components.

The mold 220 at least partially surrounds the electronic components 210 and/or 212 and is coupled to the substrate 202. The mold 220 has a top side, and a first mold sidewall, a second mold sidewall, a third mold sidewall, and a fourth mold sidewall (i.e., collectively mold sidewalls). The mold 220 may include one or more of the following materials: Epoxy resin with fused silica filler or any other organic filler material, but is not so limited. For example, the mold 220 may be any material that can be deposited, formed or molded over the electronic components 210 and/or 212 and that provides mechanical support, and environmental protection for the IC package 200 and the electronic components 210 and/or 212.

The adhesive layer 230 is an optional layer. The adhesive layer 230 may be formed over the top side of the mold 220 and under the first shield 232. In one aspect, a first side of the adhesive layer 230 is directly coupled to the mold 220, and a second side of the adhesive layer 230 is directly coupled to the first shield 232. The adhesive layer 230 is configured to improve the adhesion between the first shield 232 and the mold 220. The adhesion allows the IC package 200 to better withstand the reliability tests such as being subjected to high temperatures and will help to prevent delamination. In this regard, the adhesive layer 230 increases the reliability of the IC Package 200. In one aspect, the adhesive layer may be any material having adhesive properties such as solder resist.

The adhesive layer 230 has a length, width, and height. The length of the adhesive layer 230 may be measured on the X-axis. The width of the adhesive layer 230 may be measured on the Y-axis (i.e., coming out of the page). The optional adhesive layer 230 is configured to have a length and width similar to the length and width of the first shield 232. Alternatively, the adhesive layer 230 may have a length and/or width that is smaller than the first shield 232. The height of the adhesive layer 230 may be measured on the Z axis (i.e., measured vertically).

The first shield 232 (i.e., enhanced electromagnetic shield) is located over the mold 220, and in one aspect, may be coupled directly to the mold 220. In another aspect, the first shield 232 is coupled to the optional adhesive layer 230. The first shield 232 has a top side, and a first first shield sidewall, a second first shield sidewall, a third first shield sidewall, and a fourth first shield sidewall (i.e., collectively first shield sidewalls). In one aspect, the first shield 230 is located on the top side of the mold 360, but the first shield 230 is not located on the mold 360 sidewalls.

The first shield 232 is a high permeability shield. The material of the first shield 232 may be made of a high permeability metal. Permeability refers to a material's ability to attract and conduct magnetic lines of flux. The more conductive a material is to magnetic fields, the higher its permeability. In one aspect, the material may have a permeability larger than 10 H/m. The first shield 232 may include ferromagnetic material. The first shield 232 may include any of the following materials or a combination of one or more of the following materials: Iron (Fe), Nickel (Ni), Copper (Cu), or Manganese (Mn), however it is not so limited.

The first shield 232 is made of a material selected to have a large grain size relative to the second shield. A larger grain size provides improved electromagnetic shielding as compared with materials having a smaller grain size.

The first shield 232 has a length, width, and height. The length of the first shield 232 may be measured on the X-axis. The width of the first shield 232 may be measured on the Y-axis (i.e., coming out of the page). The length and width of the first shield 232 may be determined by those of skill in the art. For example, the length and width of the first shield 232 may be large enough to cover the electronic components 210 and 212 or may be large enough to cover the substrate 202. The optional adhesive layer 230 is configured to have a length and width similar to the length and width of the first shield 232. Alternatively, the adhesive layer 230 may have a length and/or width that is smaller than the first shield 232. The height of the first shield 232 may be measured on the Z axis (i.e., measured vertically). For example, the height of the first shield 232 may be measured by the height of the first shield sidewalls. In order to keep the form factor of the IC package 200 small, the height of the first shield 232 may be kept small. The height of the first shield 232 may be in the range of about 100 nm to 300 μm. In one aspect, the height of the first shield 232 may be about 100 nm. In another aspect, the height of the first shield 232 may be about 500 nm.

The second shield 240 is located over the first shield 232. The second shield 240 may at least partially enclose the first shield 232, and the molded electronic components 210 and 212, as well as the optional adhesive 230. In one aspect, the second shield 240 may be coupled directly to the first shield 232. The second shield 240 is located over the first shield 232 sidewalls, and over the mold 220 sidewalls so that the second shield 240 encompasses the IC package 200. The second shield 240 is also located over the substrate 202 sidewalls and is coupled to ground via the substrate 202 (i.e., through the substrate 202 ground connection). In one aspect, the second shield 240 is sputtered over the first shield 232 including the first shield sidewalls, and the mold sidewalls. The technique of sputtering may be used so that the second shield 240 is thinner as compared with using other techniques. In another aspect, the second shield 240 has a smaller grain size as compared with the first shield 230.

The second shield 240 has a length, width, and height. The length of the second shield 240 may be measured on the X-axis. The width of the second shield 240 may be measured on the Y-axis (i.e., coming out of the page). The length and width of the second shield 240 may be determined by those of skill in the art. For example, the length and width of the second shield 240 may be large enough to cover the electronic components 210 and 212 or may be large enough to cover the substrate 202, as well as cover the first shield 232. The height of the second shield 240 may be measured on the Z axis (i.e., measured vertically). The height of the second shield 240 may be measured as the distance from the top side of the first shield 232 to a top side of the second shield 240. Alternatively, the height of the second shield 240 may be measured as the distance from a bottom side of the second shield 240 to the top side of the second shield 240. In order to keep the form factor of the IC package 200 small, the height of the second shield 240 may be kept small. The height of the second shield 240 may be in the range of about 0.5-19 μm.

Together, the first shield 232 and the second shield 240 may have a total shield height of about less than 319 μm. In another aspect, the total shield height may be of about less than 119 μm.

The arrangement of the first shield 232 over the second shield 240 may be repeated. For example, a third shield (not shown) may be located over the second shield 240, where the third shield is a high permeability shield. Furthermore, a fourth shield (not shown) may be located over the third shield (i.e., where the third shield is a high permeability shield). The fourth shield may be a high conductivity shield or be similar to the second shield 240.

In comparison to conventional electromagnetic conformal shielding, the disclosed integrated circuit package 200 with enhanced electromagnetic shield has a high shielding effectiveness over a wide frequency range covering 1 MHz-10 GHz. For instance, the first shield 232 increases the shielding effectiveness in the lower frequency range <3 GHz, whereas the second shield 240 contributes at higher frequencies >3 GHz. Moreover, because the first shield 232 is a thin metal (e.g., about 300 um or less), it shortens the sputtering process and therefore reduces costs.

### Exemplary Sequence for Manufacturing an Integrated Circuit Package Comprising an Enhanced Electromagnetic Shield

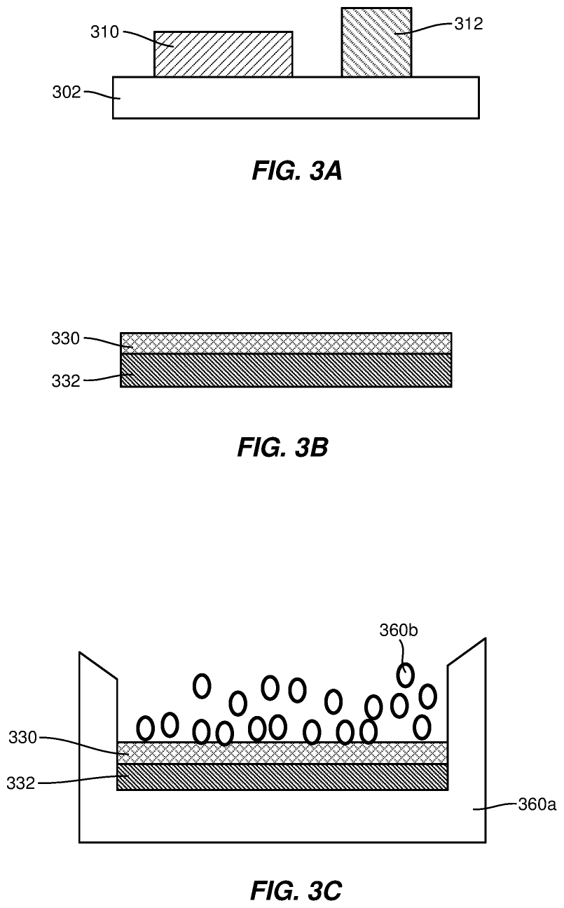

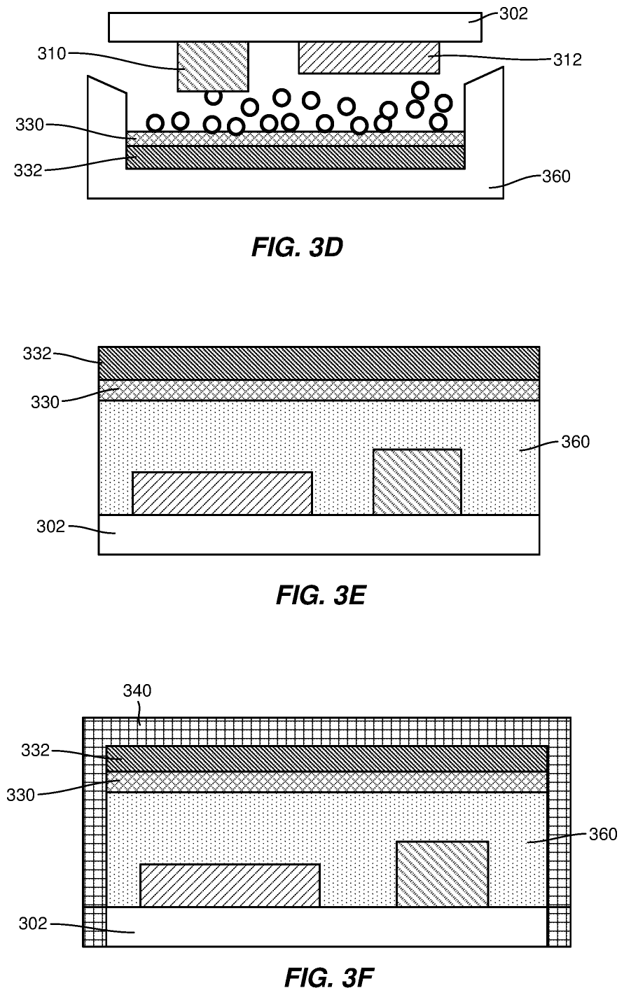

In some implementations, manufacturing an integrated circuit package comprising an enhanced electromagnetic shield includes several processes. FIG. 3 (which includes FIGS. 3A-3F) illustrates an exemplary sequence for manufacturing an integrated circuit package comprising an enhanced electromagnetic shield. In some implementations, the sequence of FIGS. 3A-3F may be used to manufacture the IC package of FIG. 2 described in the present disclosure. FIG. 3A-3F will now be described in the context of manufacturing the IC Package that includes the enhanced electromagnetic shield of FIG. 2.

It should be noted that the sequence of FIG. 3A-3F may combine one or more stages to simplify and/or clarify the sequence. In some implementations, the order of the processes may be changed or modified.

FIG. 3A illustrates electronic components 310 and 312 coupled to a substrate 302. In one aspect the electronic components 310 and 312 are surface mounted to the substrate 302. The electronic component 310 may be an IC, a die, a passive device or any other type of electronic component. The electronic component 312 may be an IC, a die, a passive device or any other type of electronic component. The substrate 302 may only have a single electronic component (e.g., one of 310 or 312) or may have many electronic components coupled to it.

The substrate 302 may be a package substrate. Alternatively, at least one of the electronic components 310 or 312 and the substrate 302 together may comprise a wafer level package.

FIG. 3B illustrates the formation of a first shield 332. An optional adhesive layer 330 may be printed on one side of the first shield 332. Alternatively, other methods may be used to provide the optional adhesive layer 330 on one side of the first shield 332.

FIG. 3C illustrates putting the first shield 332 with the optional adhesive 330 (if desired) into a mold chase 360a for disbursement of mold granule 360b (e.g., mold 360). The first shield 332 is located over the mold granule 360b (e.g., mold 360) and not on any mold 360 sidewalls. In this aspect, the mold 360 in the form of mold granule 360b is disbursed onto the optional adhesive layer 330 and the first shield 332. In another aspect, the mold 360 in the form of mold granule 360b is disbursed directly onto the first shield 332. A release film, not shown, may be located between the mold chase 360a and the first shield 332 to later aid in releasing the mold chase 360a.

FIG. 3D illustrates the coupling of the structure of FIG. 3A to the structure of FIG. 3C. In one aspect, compression is used to press the substrate and the electronic components 310 and 312 into the mold granule 360b (e.g., mold 360), the optional adhesive 330 and the first shield 332. Utilizing compression, the optional adhesive 330 and the first shield 332 will adhere to the mold 360. The mold 360, then surrounds the electronic components 310 and 312. Accordingly, coupling of the first shield 332 over the mold 360 occurs in a single process step. In other words, the electronic components 310, and 312 become “packaged” through the compression. In another aspect, thermal compression may be used. In another aspect (not shown), the first shield 332 may be laminated on the mold 360. Other known methods may also be used for the packaging.

FIG. 3E illustrates the structure of FIG. 3D after releasing the mold chase 360a, leaving the integrated circuit package including the first shield 332, the mold 360, the electronic components 310 and 312 and the substrate 302. Further, FIG. 3E illustrates the structure of FIG. 3D after dicing.

FIG. 3F illustrates an IC package such as IC package 200, including a second shield 340. The second shield 340 is deposited over the first shield 332 and surrounds the first shield 332, the adhesive 330, and the mold 360. The second shield 340 may be sputtered onto the first shield 332.

The IC package of FIG. 3F may include additional elements not shown such as dielectric layers, passivation layers, metal layers, and electronic components embedded in the substrate 302 or in a silicon substrate of one of the electronic components 310 or 312.

### Exemplary Flow Diagram of a Method for Manufacturing an Integrated Circuit Package Comprising an Enhanced Electromagnetic Shield

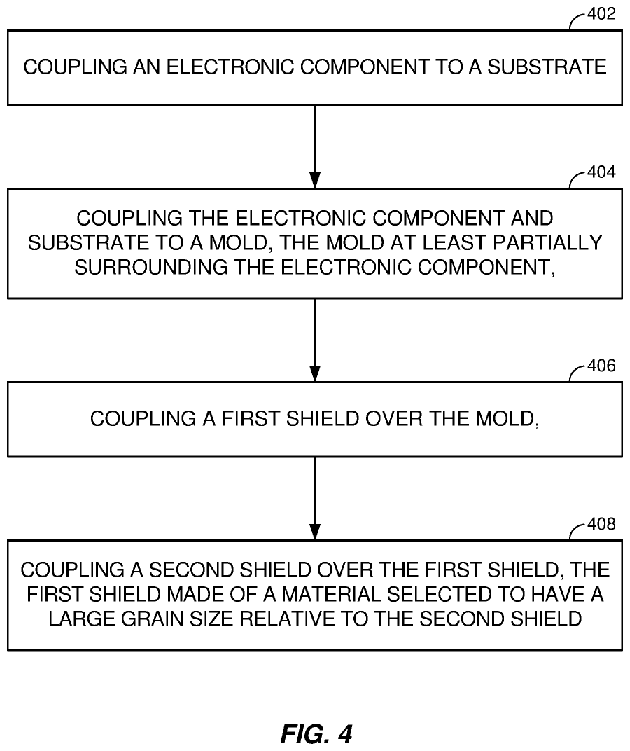

FIG. 4 illustrates an exemplary flow diagram of a method for manufacturing an integrated circuit package including an enhanced electromagnetic shield. It should be noted that for the purpose of clarity and simplification, the flow diagram of FIG. 4 does not necessarily include all the steps of manufacturing a substrate that includes one or more embedded interconnects. Moreover, in some instances, several steps may have been combined into a single step to simplify the description of the sequences.

As shown in FIG. 4, the method, at step 402, includes coupling an electronic component to a substrate.

At step 404, the method includes coupling the electronic component and substrate to a mold, the mold at least partially surrounding the electronic component.

At step 406, the method includes coupling a first shield over the mold.

At step 408, the method includes coupling a second shield over the first shield, wherein the first shield is a high permeability shield.

### Exemplary Electronic Devices

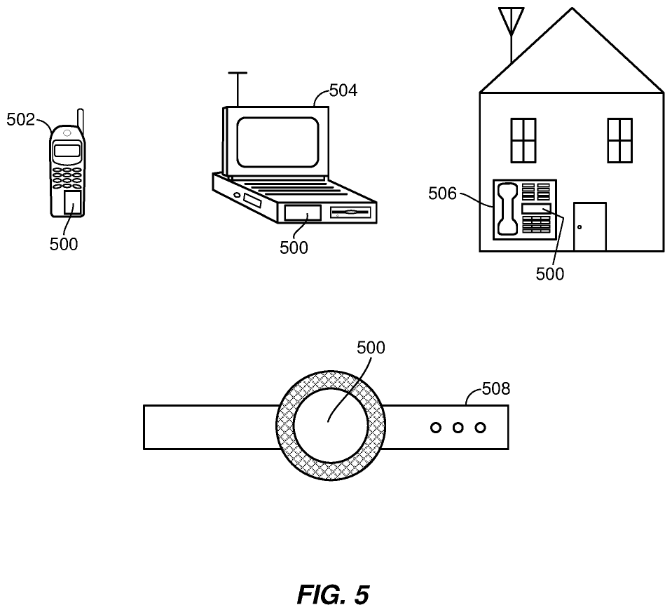

FIG. 5 illustrates various electronic devices that may be integrated with any of the aforementioned integrated circuit package including an enhanced electromagnetic shield. For example, a mobile phone device 502, a laptop computer device 504, a fixed location terminal device 506, a wearable device 508 may include an integrated device 500 as described herein. The integrated device 500 may be, for example, any of the substrate, integrated circuits, dies, integrated devices, integrated device packages, integrated circuit devices, device packages, integrated circuit (IC) packages, package-on-package devices described herein. The devices 502, 504, 506, 508 illustrated in FIG. 5 are merely exemplary. Other electronic devices may also feature the integrated device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIG. 2 through FIG. 4 may be rearranged and/or combined into a single component, process, feature or function or embodied in several components, processes, or functions. Additional elements, components, processes, and/or functions may also be added without departing from the disclosure. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “traverse” as used herein, means to go across and includes going all the way across an object or partially across an object.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package, comprising:
a substrate;
an electronic component coupled to the substrate;
a mold at least partially surrounding the electronic component and coupled to the substrate;
a first shield located over the mold; and
a second shield located over the first shield, wherein the first shield is a high permeability shield.

2. The package of claim 1, wherein the first shield has a permeability larger than 10 H/m.

3. The package of claim 1, wherein the first shield has a higher permeability relative to the second shield.

4. The package of claim 1, wherein the first shield has a large grain size relative to the second shield.

5. The package of claim 1, further comprising an adhesive layer between the first shield and the mold, the adhesive layer coupled to the mold.

6. The package of claim 5, wherein the adhesive layer is solder resist.

7. The package of claim 5, wherein the adhesive layer is configured to have a length and a width similar to a length and a width of the first shield.

8. The package of claim 1, further comprising a plurality of mold sidewalls and a plurality of first shield sidewalls, wherein the second shield is located over the plurality of mold sidewalls and the plurality of first shield sidewalls.

9. The package of claim 8, further comprising a plurality of substrate sidewalls, wherein the second shield is located over the plurality of substrate sidewalls.

10. The package of claim 8, wherein the first shield is not located on the plurality of mold sidewalls.

11. The package of claim 9, further comprising:
a third shield located over the second shield, wherein the third shield is a high permeability shield, and wherein the first shield is not located on the plurality of mold sidewalls.

12. The package of claim 11, further comprising a fourth shield located over the third shield.

13. The package of claim 1, wherein the first shield is configured to have a height of about 100 nm to about 300 μm.

14. The package of claim 10, wherein the second shield is configured to have a height of about 0.5 μm to 19 μm.

15. The package of claim 1, wherein the total shield height including the first shield and the second shield is less than about 319 μm.

16. The package of claim 1, wherein the first shield includes ferromagnetic material.

17. The package of claim 16, wherein the first shield includes iron and nickel or an alloy thereof.

18. The package of claim 1, wherein the second shield is a sputtered shield.

19. The package of claim 18, wherein the second shield includes at least one of titanium, nickel, chromium, or a combination thereof.

20. The package of claim 1, wherein the package is incorporated into a device selected from a group consisting of a music player, a video player, an entertainment unit, a navigation device, a communications device, a mobile device, a mobile phone, a smart phone, a personal digital assistant, a fixed location terminal or server, a tablet computer, and a laptop computer, and further including the device.

21. A method of fabricating an integrated circuit package, comprising:
coupling an electronic component to a substrate;
coupling the electronic component and the substrate to a mold, the mold at least partially surrounding the electronic component;
coupling a first shield over the mold; and
coupling a second shield over the first shield, wherein the first shield is a high permeability shield.

22. The method of claim 21, further comprising:
coupling the first shield to a mold chase, the mold chase including a release film located between the first shield and the mold chase;
providing the mold over the first shield in the form of a mold granule; and
coupling the electronic component and substrate to the mold chase, the mold, and the first shield through thermal-compression.

23. The method of claim 22, further comprising releasing the mold chase and the release film.

24. The method of claim 23, further comprising sputtering the second shield over the first shield.

25. The method of claim 21, further comprising sputtering the second shield over the first shield.

26. The method of claim 22, wherein the first shield has a large grain size relative to the second shield.

27. The method of claim 21, further comprising:
providing an adhesive layer between the first shield and the mold, the adhesive layer coupled to the mold and having a length and a width similar to a length and a width of the first shield.

28. The method of claim 21, wherein the mold includes a plurality of mold sidewalls, the first shield includes a plurality of first shield sidewalls, and the substrate includes a plurality of substrate sidewalls, the second shield located over the mold sidewalls, the plurality of first shield sidewalls, and the plurality of substrate sidewalls.

29. The method of claim 28, wherein the first shield is not located on the plurality of mold sidewalls.

30. The method of claim 21, wherein the first shield is configured to have a height of about 100 nm to about 300 μm.

31. The package of claim 21, wherein the second shield is configured to have a height of about 0.5 μm to 19 μm.

32. The package of claim 21, wherein the first shield includes iron and nickel or an alloy thereof.
